(19) United States
(12) Patent Application Publication
(10) Pub. No.: US 2008/0047135 A1
(43) Pub. Date: Feb. 28, 2008

(54) Rigid flex printed circuit board

(75) Inventor: Shawn Arnold, Capitola, CA (US)

Correspondence Address: RAYMOND R. MOSER JR., ESQ.;MOSER IP LAW GROUP, 1030 BROAD STREET, 2ND FLOOR, SHREWSBURY, NJ, 07702, US

(73) Assignee: ChipStack Inc., Saratoga, CA (US)

(21) Appl. No.: 11/895,922

(22) Filed: Aug. 28, 2007

Related U.S. Application Data
(60) Provisional application No. 60/823,679, filed on Aug. 28, 2006.

(51) Int. Cl. H05K 3/00

(52) U.S. Cl. 29/829

(57) ABSTRACT

A rigid flex circuit board and a method of fabricating a rigid flex circuit board. The method comprising forming a stack of at least two layers of at least one of a flexible material, prepreg material, insulative material, or conductive material over a flexible core to form a structure, wherein the structure comprises a first rigid portion, a second rigid portion, a flexible portion extending between the first and second rigid portions, and a removable rigid portion extending between the first rigid portion and the second rigid portion, processing the structure to form interconnects; and removing the removable rigid portion.

### CROSS-REFERENCE TO RELATED APPLICATIONS

This application claims benefit of U.S. provisional patent application Ser. No. 60/823,679, filed Aug. 28, 2006, which is herein incorporated by reference.

### BACKGROUND OF THE INVENTION

1. Field of the Invention

Embodiments of the present invention generally relate to a multilayer rigid flex printed circuit board.

2. Description of the Related Art

Rigid flex circuit boards comprise at least one portion that is rigid and another portion that is flexible such that the rigid portion can be manipulated when installing the circuit board. The rigid portions contain electrical traces that are conductively connected through the flexible portion to interconnect at least two rigid portions. In a typical rigid flex printed circuit board construction, a flexible printed circuit portion extends from one or more edges around the periphery of rigid portion or portions. The rigid portions are typically used for mounting electronic components, connectors and hardware. The flex portion on the other hand serves to connect the various rigid portions while allowing rigid portions to be located in hardware equipment on different planes or at different angular orientations with respect to each other.

In certain applications, the flexible portion extends from a single rigid portion and terminates into “fingers”; thus forming a flexible cable. The fingers can be used to attach to zero insertion force (ZIF) connectors.

As the density of electronic circuitry has become greater over the years, more complex multilayer rigid flex circuit boards have evolved with boards now having a dozen or more patterned conductive circuit layers. The fabrication of such boards includes materials such as pre-impregnated (prepreg) fiberglass epoxy sheet spacers or bonding material, in various polyimide, aramid or epoxy/glass copper clad laminates. The use of some materials leads to a number of problems including moisture absorption, cracking, and fractures. Furthermore, a serious problem that arises from some manufacturing techniques is the fracturing of the copper foil when sanding processes are applied to planarize the vias within a rigid portion of the rigid flex circuit board. An unequal sanding force across the rigid-to-flex interface causes the copper foil at the interface to fracture.

Therefore, there is a need in the art for an improved rigid flex circuit boards as well as an improved method of manufacturing rigid flex circuit boards.

### SUMMARY OF THE INVENTION

Embodiments of the present invention comprise a rigid flex circuit board and a method of fabricating a rigid flex circuit board. The method comprising forming a stack of at least two layers of at least one of a flexible material, prepreg material, insulative material, or conductive material over a flexible core to form a structure, wherein the structure comprises a first rigid portion, a second rigid portion, a flexible portion extending between the first and second rigid portions, and a removable rigid portion extending between the first rigid portion and the second rigid portion, processing the structure to form interconnects; and removing the removable rigid portion.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a top view of a rigid flex circuit board in accordance with one embodiment of the present invention;

FIG. 2 depicts a top view of a rigid flex circuit board during manufacture showing the lateral slots having been previously formed in layers of the circuit board in accordance with one embodiment the present invention;

FIG. 3 depicts a top view of the structure of the rigid flex circuit board indicating where longitudinal slots are cut into the circuit board;

FIG. 4 depicts a side cross sectional view of a stack of layers that forms the rigid flex circuit board in accordance with the present invention;

FIG. 5 depicts a cross sectional view of the rigid flex circuit board after final processing;

FIG. 6 depicts a side cross sectional view of a stack of layers that form a rigid flex cable in accordance with a second embodiment of the invention;

FIG. 7 depicts a cross sectional view of the embodiment of FIG. 6 at an intermediary fabrication step;

FIG. 8 depicts a cross sectional view of the embodiment of FIG. 6 and 7 after a final fabrication step;

FIG. 9 depicts a cross sectional view of a stack of layers that form a third embodiment of a rigid flex cable;

FIG. 10 depicts a cross sectional view of the embodiment of FIG. 9 at an intermediary fabrication step; and

FIG. 11 depicts a cross sectional view of the embodiment of FIGS. 9 and 10 after a final fabrication step.

### DETAILED DESCRIPTION

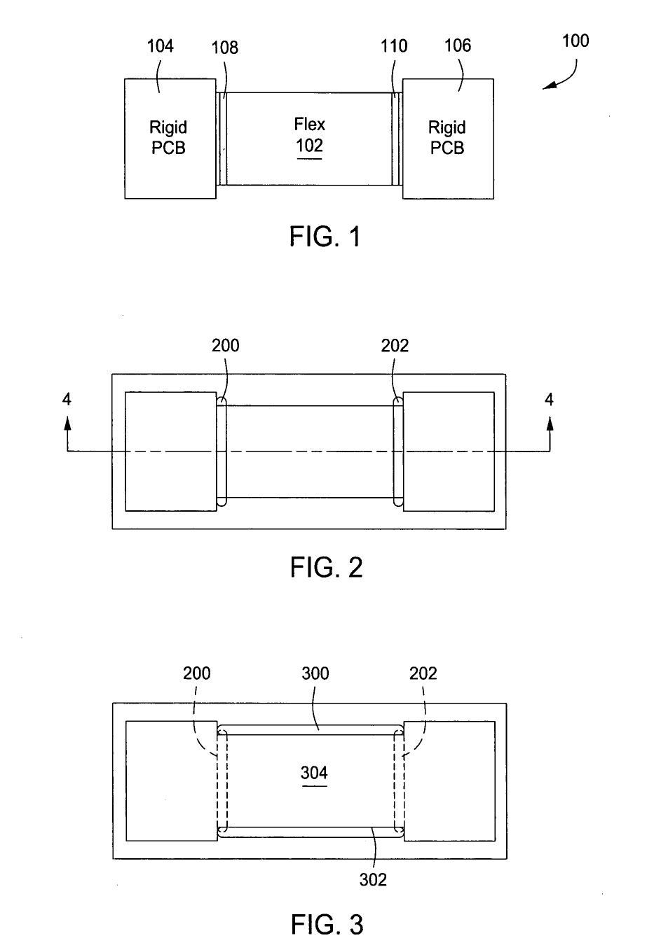

FIG. 1 depicts a top view of a rigid flex circuit board 100 comprising rigid sections 104 and 106 and a flexible section 102. To facilitate a transition between the rigid sections 104 and 106 and the flexible section 102 a pair of cantilevers 108 and 110 extend from the rigid sections 104 and 106 onto the flexible section 102. The cantilevers are formed as a “dual lip” structure as discussed below.

FIG. 2 and FIG. 3 should be view together to understand one embodiment of the fabrication process of the present invention. FIG. 2 depicts a top view of the rigid flex circuit 100 having the rigid sections 104 and 106 and the flexible section 102 spaced therebetween. To facilitate creating the flexible portion, a pair of lateral slots 200 and 202 are routed, milled or otherwise formed into a stack of layers that comprise the rigid flex circuit board 100. Generally, the lateral slots 200 and 202 are preformed in the layers prior to stacking the layers. After all the processing is complete, longitudinal slots 300 and 302 are routed into the structure to release a central portion 304. Until the central portion 304 is released, the structure is rigid.

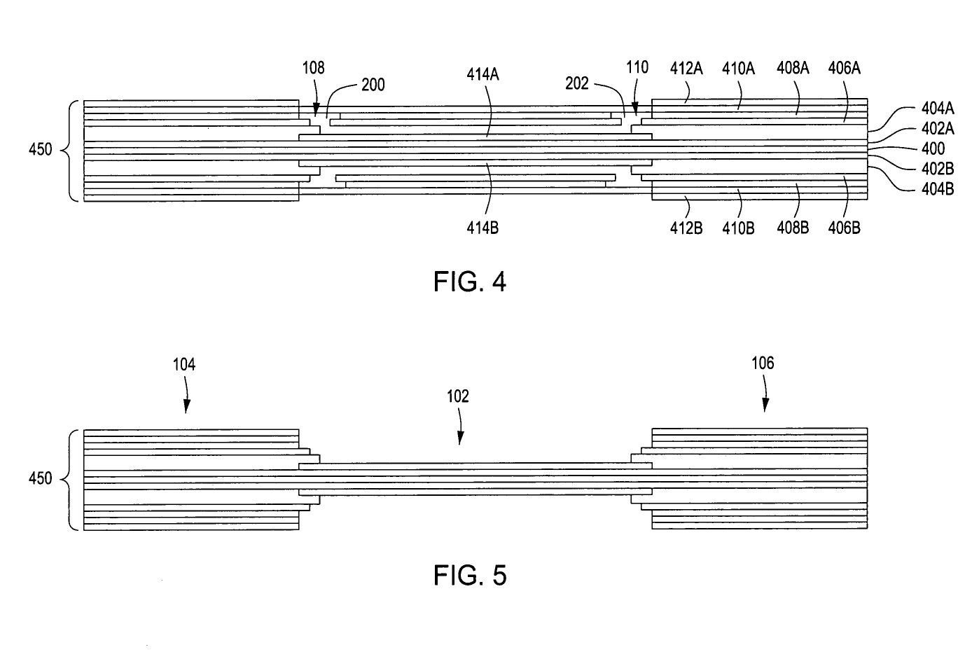

FIG. 4 depicts a side, cross sectional view of FIG. 2 along lines 4-4. The stack of materials that form the stack 450 comprise the flexible core 400 generally comprising a flexible polyimide, FR-4, CUTE® or any other flexible core material that is clad with copper 402A and 402B on at least one side. Generally, circuit traces or planes are formed from the copper on both sides of the core. These traces/planes carry the electrical signals to/from the rigid portions of the circuit board across the flexible portion 102. A layer 414A and 414B of flexible soldermask is applied to an area that defines the flexible portion 102 such that than insulative layer 414A and 414B is formed that protects the copper traces on the flexible core. A layer 404A and 404B of prepreg is applied to the assembly, where the layers 404A and 404B define an aperture in which is the insulative layer 414A, 414B. The layers 404A and 404B overlap the edge of the layers 414A and 414B. Atop the layer of prepreg is positioned a blank FR4 core 406A and 406B that is cured to be stiff. The layers 406A and 406B comprise a lateral slot 202, where the edge of layers 406A and 406B partially overlap the edge of layers 404A and 404B. This forms the “dual lip” cantilever. In this manner, the dual lip cantilever 110, 108 provides a strong edge along which the flexible portion 102 bends. Atop of the cured FR4 core are layers of prepreg 408A and 408B. In one embodiment of the invention, these layers 406A, 406B and 408A, 408B, comprise the lateral slots 200, 202 that are preformed in the layers before stacking. Note that the slots are aligned with the dual lip cantilever 108 and 110.

Atop those layers is positioned a copper foil 410A and 410B in which traces and planes will be etched to facilitate mounting of integrated circuits to the rigid portion of the board. Subsequent to applying the copper foil, the copper foil is etched using photomask layer 412A and 412B to define traces for the circuitry on the rigid portions 104 and 106 of the circuit board 100. Additionally, via holes may be drilled and plated, as well as sanded, as needed. Upon etching the copper foil to form traces, the copper foil in the flexible portion 102 is removed.

FIG. 3 depicts the longitudinal slots 300 and 302 having been cut on either side of the flexible region. The longitudinal slots 300 and 302 are routed, milled or otherwise formed into the circuit board to contact the lateral slots 200 and 202. In this manner, the layers 406A, 406B, 408A and 408B above and below the flexible portion 102 that do not form part of this flexible portion are released from the structure allowing the rigid portions 104 and 106 to be freed and become movable. A cross sectional view of the rigid flex circuit board is shown in FIG. 5. The final form is a multilayer, e.g., four layer, rigid flex circuit board 100. Importantly, the entire circuit board structure is competed prior to releasing the flexible portion. As such, the manufacturing process is performed upon a stable, rigid structure.

The routing bit that is used for forming the lateral and longitudinal slots is in the range of 0.018 to 0.022 inches in diameter. The lip that forms the cantilever has a length from the rigid portion of approximately 0.010 inches. The flexible core may be CUTE® manufactured by Hitachi, flexible FR-4, a more traditional polyimide material or any other flexible core material. Using the rigid support during manufacturing that spans the flexible portion, sanding and other planarization techniques for the conductive foil on the rigid portions of the board can be performed without causing “kneeing” or other problems with board manufacture.

To summarize the manufacturing process, the process begins with a flexible core material supporting a pattern of circuit traces on both surfaces, an insulative layer of flexible photomask material is applied over both sides of the flexible portion, and a first layer of prepreg material having a precut opening is positioned over the core material. The opening is aligned with the insulative layer. Additional layers of FR-4 and prepreg material are cut (routed) to form a lateral slot that will be aligned with a lateral edge of the flexible portion. These layers are stacked on both sides of the structure. A layer of foil is applied to both sides of the structure. The entire stack is cured at a pressure, temperature and an amount of time sufficient to harden the materials of the stack (except for the flexible core, its traces, and the flexible insulative layer). Once cured, the foil layer is drilled and blind or buried interconnects are filled. Sanding is performed, if necessary. Then, the through holes are drilled and plated. The circuit traces are patterned and etched into the foil. Longitudinal slots are cut (routed) into the stack to connect the lateral slots such that a region above the flexible portion is removed (released). In this manner, the entire processing of the rigid flex circuit board is performed while the structure is rigid. The last process step releases the flexible portion to complete the rigid flex circuit board.

One other feature depicted in FIG. 4 is the use of the prepreg material 408A and 408B having an edge that is cut back from the edge of the lateral slot 200, 202, i.e., the slot in layers 408A, 408B is wider than the slot inlayers 406A and 406B. By using such a prepreg cut back, during curing, the prepreg material will not flow into the lateral slot 200, 202.

Generally, to align all of the layers that are stacked and then cured to form the rigid flex circuit board 100, an alignment system such as ACCULINE® of the Multiline Company of Farmingdale, N.Y. which uses a four slot printed circuit board punch and a plurality of pins to hold and retain the circuit board stack during assembly and curing.

In one embodiment of the invention, the insulating material of the flexible soldermask is an ultraviolet curable material fabricated by Lackwerke Peter GMBH or the heat curable coating preparation sold by ASI-Coates.

In one embodiment of the invention, after all of the layers have been stacked the plates are aligned on either side of the stack of material and pressure is applied at 300 to 350 psi at a temperature of 350° for several hours to form a hard unitary board structure. These process parameters are exemplary, the parameters will vary depending upon the materials used and the respective thicknesses of the materials. Once cured, the outer copper layers are then drilled, plated, patterned and etched, both to form the desired circuit features in the layer and to remove the copper portion overlying the flexible portion.

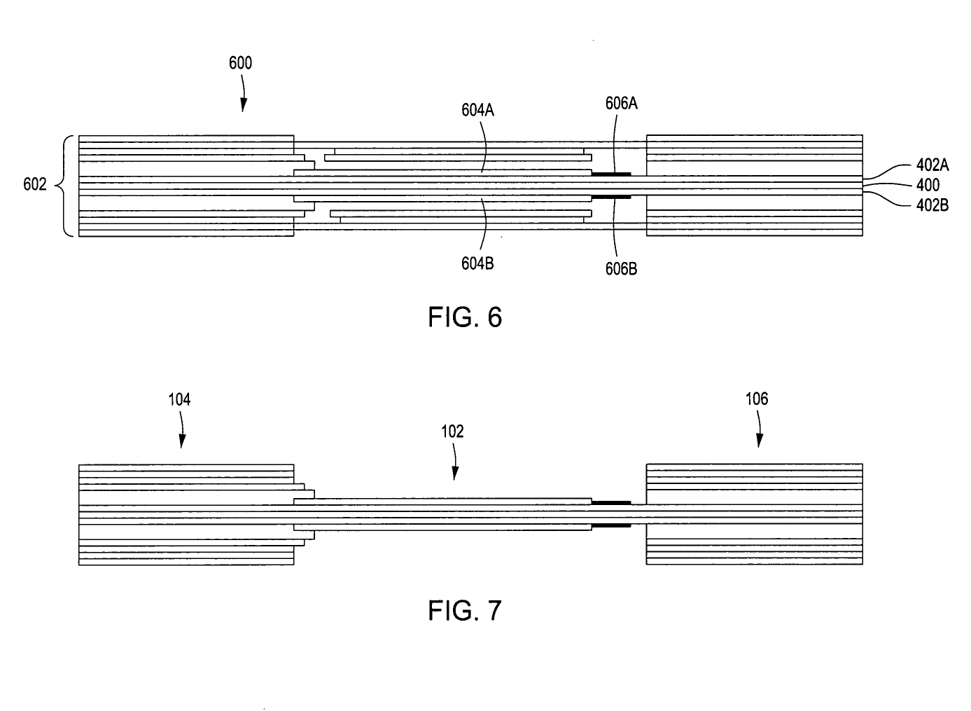

FIGS. 6, 7 and 8 depict cross sectional views of a second embodiment of the invention at various stages during fabrication. This embodiment is a rigid flex cable having a rigid end 800 and a flexible end 802, where the flexible end 802 is adapted for insertion into a zero insertion force (ZIF) connector.

FIG. 6 depicts a structure 600 comprising a stack 602 of layers being substantially similar to the stack 450 of FIG. 400. The difference between stack 450 and stack 600 is that the flexible insulator layer 604 does not extend completely across the flexible portion 102. Additionally, gold (or other highly conductive material) is deposited to form at least one pad 606A and 606B at the distal end of the traces on the foil layers 402A, 404B located on both sides of the flexible portion. The position and deposition of the at least one pad occurs during formation of the traces prior to forming the stack 602.

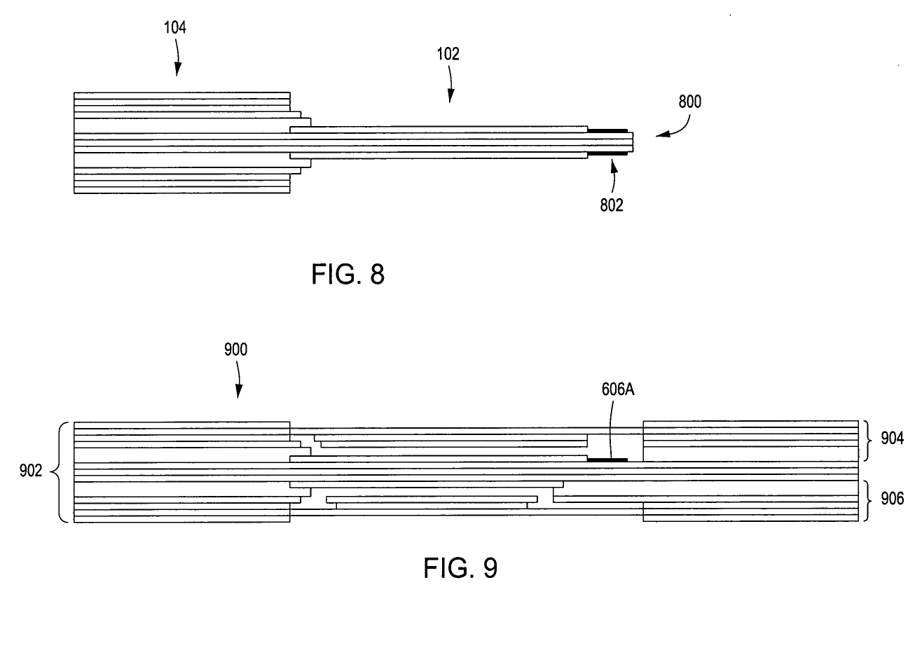

As shown in FIG. 7, the structure 600 is processed and longitudinal slots cut to release the flexible portion 102 between the rigid portions 104 and 106. As shown in FIG. 8, the rigid portion 106 is removed from the distal end of the flexible portion 102. This removal is facilitated by routing, punching, scribing, snapping or otherwise detaching the rigid portion 106. The result is a rigid flex cable 800 having fingers 802 positioned along the distal end of the flexible portion 102. These fingers 802 are adapted (sized and shaped) to insert into a double sided zero insertion force (ZIF) connector.

FIGS. 9, 10 and 11 depict a series of cross sectional views of a third embodiment of the invention during various fabrication steps of making a rigid flex cable used for single sided ZIF connectors. The structure 900 is similar to the structure 600 of FIG. 6, except the top and bottom arrangements are asymmetrical. The top portion 904 of a stack 902 contains the at least one conductive contact (pad 606A). The bottom portion 906 is arranged in a manner similar to the structure 600, i.e., a rigid portion.

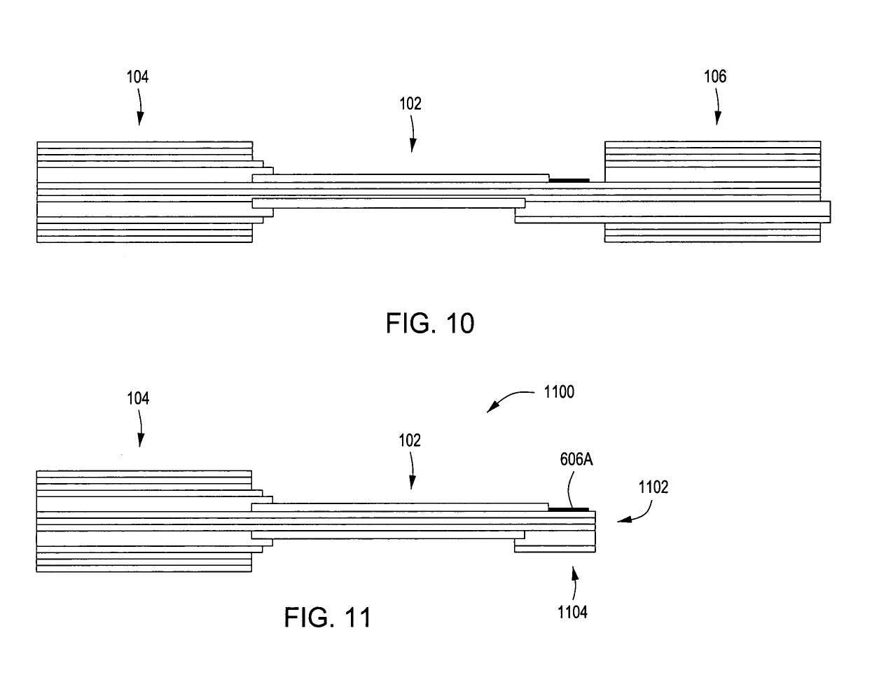

As shown in FIG. 10, when released, the flexible portion 102 spans between rigid portions 104 and 106. A portion of portion 106 is removed at the pad 606A. Consequently, the pad 606A that forms part of a finger 1102 rests upon a rigid portion 1104. The rigid portion 1104, flexible portion 102 and rigid support 1104 form a rigid flex cable 1100 that comprises a finger 1102 adapted for insertion into a one-sided ZIF connector.

While the foregoing is directed to embodiments of the present invention, other and further embodiments of the invention may be devised without departing from the basic scope thereof, and the scope thereof is determined by the claims that follow.

What is claimed is:

1. A method of fabricating a rigid flex circuit board, comprising:
forming a stack of at least two layers of at least one of a flexible material, prepreg material, insulative material, or conductive material over a flexible core to form a structure, wherein the structure comprises a first rigid portion, a second rigid portion, a flexible portion extending between the first and second rigid portions, and a removable rigid portion extending between the first rigid portion and the second rigid portion;
processing the structure to form interconnects; and
removing the removable rigid portion.

2. The method of claim 1, further comprising forming a dual lip cantilevers extending from the first and second rigid portion onto the flexible portion, wherein the dual lip cantilevers comprise a plurality of material layers.

3. The method of claim 1, wherein the flexible core comprises at least one of FR-4, flexible polyimide or CUTE material.

4. The method of claim 1, wherein a first surface and a second surface of the structure are asymmetric.

5. The method of claim 1 further comprising removing the second rigid portion to adapt the flexible portion for insertion into a zero insertion force connector.

6. A method of fabricating a rigid flex circuit board, comprising:
forming a structure by applying layers of at least one of an insulative layer or a prepreg material to at least one of a first surface or a second surface of a flexible core, wherein the structure comprises a first rigid portion, a second rigid portion, a flexible portion extending between the first rigid portion and the second rigid portion and a removable rigid portion extending between the first rigid portion and the second rigid portion;
applying a foil layer on at least one of a first surface or a second surface of the structure;
curing the structure;
at least one of drilling or plating holes into the structure;
removing at least one portion of the foil layer to form circuit traces upon at least one of a first surface or a second surface of the structure; and
removing the removable rigid portion from the structure.

7. The method of claim 6 further comprising sanding of the structure prior to removing the removable rigid portion.

8. The method of claim 6, wherein the flexible core comprises at least one of FR-4, flexible polyimide, or CUTE material.

9. The method of claim 6 further comprises forming at least one dual lip cantilever adjacent a junction of at least one of the first or second rigid portions and the flexible portion.

10. The method of claim 6 further comprising removing the second rigid portion to adapt the flexible portion for insertion into a zero insertion force connector.

11. A rigid flex circuit board, comprising:
a first rigid portion;
a second rigid portion;
a flexible portion extending between the first rigid portion and the second rigid portion; and
a removable rigid portion extending between the first rigid portion and the second rigid portion.

12. The rigid flex circuit board of claim 11 wherein the first rigid portion, the second rigid portion, the flexible portion and the removable portion comprise:
a flexible core and at least one layer of at least one of a prepreg material, insulative material, or conductive material.

13. The rigid flex circuit board of claim 11 wherein the removable rigid portion comprises a plurality of rigid layers.

14. The rigid flex circuit board of claim 11 further comprising a dual lip cantilever extending from at least one of the first or second rigid portions over a portion of the flexible portion.

15. The rigid flex circuit board of claim 14 wherein the dual lip cantilever comprises a plurality of layers.

16. The rigid flex circuit board of claim 15 wherein the dual lip cantilever comprises a first layer extending further over a portion of the flexible portion than a second layer.
